(19) United States
(12) Patent Application Publication
(10) Pub. No.: US 2011/0249417 A1
(43) Pub. Date: Oct. 13, 2011

(54) ANISOTROPIC CONDUCTIVE RESIN, SUBSTRATE CONNECTING STRUCTURE AND ELECTRONIC DEVICE

(75) Inventor: Masahito Kawabata, Kanagawa (JP)

(73) Assignee: PANASONIC CORPORATION, Osaka (JP)

(21) Appl. No.: 13/140,332

(22) PCT Filed: Jul. 15, 2009
(86) PCT No.: PCT/JP2009/003337

§ 371 Date: Jun. 16, 2011

(30) Foreign Application Priority Data
Dec. 19, 2008 (JP) 2008-324611

(51) Int. Cl. H05K 7/00; H01B 1/22; H05K 1/02

(52) U.S. Cl. 361/760; 174/259; 252/519.33

(57) ABSTRACT

An anisotropic conductive resin includes a thermosetting resin and an alloy. A relationship of T1<T3<T2<T4 is satisfied, where T1 is a reaction start temperature of the thermosetting resin, T2 is a reaction peak temperature of the thermosetting resin, T3 is a solidus temperature of the alloy, and T4 is a liquidus temperature of the alloy.

### TECHNICAL FIELD

The present invention relates to an anisotropic conductive resin for electrically connecting a substrate made of a soft base member to another substrate made of a hard base member, a substrate connecting structure including the anisotropic conductive resin, and electronic device using the substrate connecting structure.

### BACKGROUND ART

In electronic devices, such as portable phones, there are cases where an anisotropic conductive resin made by dispersively mixing an alloy, such as solder, into a thermosetting resin is used for connecting terminals of a substrate (a rigid substrate) made of a hard base member exhibiting low flexibility with terminals of a substrate (a flexible substrate) made of a soft base member exhibiting high flexibility (see, for example, Patent Document 1).

FIG. 18 is a cross-sectional view showing that two substrates are bonded together through thermocompression bonding by use of a related-art anisotropic conductive resin. FIG. 18 is a cross-sectional view of two substrates cut along a longitudinal direction of terminals provided on each of the substrates (a direction indicated by arrow AA shown in FIG. 18). FIG. 19 is a cross-sectional view taken along a line A-A′ shown in FIG. 18, and FIG. 20 is a cross-sectional view taken along a line B-B′ shown in FIG. 18.

In FIGS. 18 to 20, a first substrate 1 is a flexible substrate made of a translucent soft base member exhibiting high flexibility, and a plurality of terminals 3 are arranged on one surface of the first substrate 1. A second substrate 2 is a rigid substrate made of an opaque hard base member exhibiting low flexibility, and a plurality of terminals 4 are arranged on one surface of the second substrate 2. Each of the first substrate 1 and the second substrate 2 is formed into a plate shape having a first surface and a second surface opposite to the first surface.

The first substrate 1 and the second substrate 2 are heated and pressurized by a thermocompression bonding tool 60 and a pressure bonding table 61 while an anisotropic conductive resin 50 is sandwiched therebetween. Granular solders 51 contained in the anisotropic conductive resin 50 are completely liquefied when the granular solders 51 reaches a liquidus line (a temperature at which a solid comes into a perfect liquid) by thermocompression bonding from a solidus line (a temperature where the solder starts to change from a solid to a liquid). At this time, the terminal 3 of the first substrate 1 and the respective terminal 4 of the second substrate 2 are in an electrically conductive state by the solder 51 existing between the terminal 3 of the first substrate 1 and the terminal 4 of the second substrate 2. When the solder 51 reaches the liquidus line, a thermosetting resin 52 of the anisotropic conductive resin 50 is in an uncured state, and adjacent solder particles often contact one another, thereby fusing together. In FIGS. 19 and 20, reference numeral 51a designates solder particles in a contacted or fused state.

### RELATED ART DOCUMENT

### Patent Document

Patent Document 1: JP-A-8-186156

### SUMMARY OF THE INVENTION

### Problem that the Invention is to Solve

However, in a case in which little substantial temperature difference exists between the solidus line and the liquidus line of solder of the same constituent materials (e.g., Sn (tin) and Bi (bismuth)), when a solidus temperature and a liquidus temperature are lower than a hardening reaction peak temperature of a resin, the solder fuses before the resin cures. Therefore, the solder particles sometimes contact one another or fuse together between terminals or outside the terminals, which may cause an electrical short circuit between the terminals or a current leakage. As shown in FIG. 20, the solder particles are likely to enter air voids 53 existing in the thermosetting resin. In a case in which the contacted or fused solder particles 51a are present in the air voids 53, when water droplets are caused by absorption of moisture, the solder particles become a cause of an electrical short circuit between terminals of a single substrate or current leakage.

When the solidus temperature and the liquidus temperature are higher than the curing reaction peak temperature of the resin, the solder fuses after the resin cures. Therefore, the resin existing around the solder particles are in a state of an insulation film, so that a connection between desired terminals cannot be established.

In the case of Sn/58Bi (Sn accounts for 42%, and Bi accounts for 58%) solder, a solidus temperature is 139° C., and a liquidus temperature is 141° C., which results in a temperature difference ΔT is 2° C. Further, when the first substrate and the second substrate are bonded together for electrical connection purpose, terminals oppose each other. The “between the terminals” refers to a space between the terminals in a direction perpendicular to the mutually-opposing direction. That is, when a terminal of the first substrate and a terminal of the second substrate opposing each other are taken as one set, a space between the set and an adjacent set is referred to as the “between the terminals”. Further, the “between desired terminals” refers to a space between the terminals of the first substrate and the terminals of the second substrate.

The present invention was made in view of the circumstance and an object thereof is to provide an anisotropic conductive resin capable of reliably connecting terminals of a first substrate with terminals of a second substrate by an alloy when the first and second substrates are electrically connected together by thermocompression bonding by use of the anisotropic conductive resin containing a thermosetting resin and a particle alloy and capable of preventing contacting or fusing of the particle alloy between or outside the terminals of each of the first and second substrates, a substrate connecting structure including the anisotropic conductive resin, and an electronic device using the substrate connecting structure.

### Means for Solving the Problem

An anisotropic conductive resin of the present invention includes a thermosetting resin and an alloy, wherein a relationship of T1<T3<T2<T4 is satisfied, where T1 is a reaction start temperature of the thermosetting resin, T2 is a reaction peak temperature of the thermosetting resin, T3 is a solidus temperature of the alloy, and T4 is a liquidus temperature of the alloy.

According to the configuration, the solidus temperature T3 of the alloy is set between the reaction start temperature T1 and the reaction peak temperature T2 of the thermosetting resin, and the liquidus temperature T4 of the alloy is set the reaction peak temperature T2 or more. Therefore, when two substrates are electrically connected together by thermocompression bonding by use of the anisotropic conductive resin of the present invention, and in a case in which the reaction end temperature of the thermosetting resin is higher than the liquidus temperature T4 of the alloy, the thermosetting resin is not fully cured when the alloy is fused. Consequently, an inter-terminal distance (a gap) between the two substrates becomes smaller, and a wet spread of the alloy to the terminals is promoted, whereby the terminals of the two substrates can be placed in a reliably conductive state. Further, in a case in which the reaction end temperature of the thermosetting resin is lower than the liquidus temperature T4 of the alloy, even when the alloy that does not contribute to connection between the terminals of the two substrates (alloy particles existing between terminals of each of the first and second substrates or outside the terminals of each of the first and second substrates) is fused, the thermosetting resin thermally set around the alloy remains a rigid structure. Consequently, it is hard for the alloy particles to contact each other or become fused together.

A substrate connecting structure of the present invention includes: first and second substrates, each of which includes: a base member having a first surface and a second surface opposite to the first surface; and first and second wiring patterns arranged on the first surface and extending along a predetermined direction; and an anisotropic conductive resin interposed between the first surface of the first substrate and the first surface of the second substrate, wherein the base member of the first substrate has an end face intersecting the predetermined direction, wherein on an inside of the end face in which the first substrate exists, the first wiring pattern of the first substrate opposes the first wiring pattern of the second substrate, and the second wiring pattern of the first substrate opposes the second wiring pattern of the second substrate, and wherein on an outside of the end face which is opposite to the inside, the anisotropic conductive resin is exposed.

According to the configuration, since the anisotropic conductive resin is contained, the terminal of the first substrate and the terminal of the second substrate can be placed in a reliable conductive state, or it is possible to make contacting or fusing of alloy particles to hardly occur. A portion of the anisotropic conductive resin is exposed on the outside of the end face of the first substrate, whereby the end face and the first surface of the second substrate can be connected together. Further, the reaction end temperature of the thermosetting resin is set lower than the liquidus temperature T4 of the alloy, whereby the alloy particles hardly contact one another or fuse together even in a portion of the anisotropic conductive resin exposed outside of the end face of the first substrate. Therefore, a short circuit hardly occurs between the terminals of the first substrate or between the terminals of the second substrate in the exposed portion.

In the present invention, in the substrate connecting structure, the first substrate or the second substrate is a part of an electronic component.

According to the configuration, the electronic component can reliably be connected to the wiring pattern provided on the first substrate or the second substrate.

In the present invention, the substrate connecting structure includes a first electronic component provided on the second surface of the second substrate, and the first electronic component is disposed at a position opposing the anisotropic conductive resin across the second substrate. That is, the second substrate is interposed between the first electronic component and the anisotropic conductive resin, and the first electronic component is disposed so as to oppose the anisotropic conductive resin.

According to the configuration, a connection by thermocompression bonding is completed before the thermosetting resin fully cures. Hence, there is no need to apply great pressure during thermocompression bonding, and even when an electronic component is provided on the second surface of the second substrate, the electronic component is not likely to be broken during thermocompression bonding. That is, even when an electronic component is placed on the second surface of the second substrate, the first substrate and the second substrate can be electrically connected without breakage of the electronic component.

In the present invention, the substrate connecting structure includes a second electronic component provided in the base member of the second substrate, and the second electronic component is disposed at a position opposing the anisotropic conductive resin across the base member of the second substrate. That is, the base member exists between the second electronic component and the first surface of the second substrate, the base member also exists between the second electronic component and the second surface of the second substrate, and the second electronic component is disposed at a position corresponding to the anisotropic conductive resin.

According to the configuration, a connection caused by thermocompression bonding is completed before the thermosetting resin fully cures. Therefore, there is no need to apply great pressure during thermocompression bonding, and even when an electronic component is provided in the base member of the second substrate, the electronic component is not likely to be broken during thermocompression bonding. That is, even when an electronic component is provided in the base member of the second substrate, the first substrate and the second substrate can be electrically connected without breaking the electronic component.

An electronic device of the present invention includes the anisotropic conductive resin of the above-described configuration or the substrate connecting structure.

According to the configuration, a highly reliable electronic device can be implemented.

### ADVANTAGES OF THE INVENTION

According to the present invention, when a first substrate and a second substrate are electrically connected through thermocompression bonding by use of an anisotropic conductive resin including a thermosetting rein and an alloy, a terminal of the first substrate can be reliably connected to a terminal of the second substrate by setting a reaction end temperature of the thermosetting resin higher than a liquidus temperature of the alloy, and alloy particles are prevented from contacting one another or fusing together between the terminals of each of the first and second substrates or outside the terminals by setting the reaction end temperature of the thermosetting resin lower than the liquidus temperature of the alloy.

### BRIEF DESCRIPTION OF THE DRAWINGS

FIG. 1 is a cross-sectional view showing an anisotropic conductive resin of an embodiment of the present invention.

FIG. 2 is a diagram showing heat characteristics of a thermosetting resin and solder contained in the anisotropic conductive resin shown in FIG. 1.

FIG. 3 is a diagram showing the heat characteristic and a viscosity characteristic of the thermosetting resin contained in the anisotropic conductive resin shown in FIG. 1.

FIG. 4 is a diagram showing heat characteristics of a thermosetting resin exhibiting two exothermic reaction peaks and solder.

FIG. 5 is a cross-sectional view of a substrate connecting structure using the anisotropic conductive resin shown in FIG. 1 in a state in which a temperature of the thermosetting resin in the anisotropic conductive resin is in the vicinity of a curing reaction starting point.

FIG. 6 is a cross-sectional view taken along line A-A′ shown in FIG. 5.

FIG. 7 is a cross-sectional view taken along line B-B′ shown in FIG. 5.

FIG. 8 is a cross-sectional view of the substrate connecting structure using the anisotropic conductive resin shown in FIG. 1 in a state in which the temperature of the thermosetting resin in the anisotropic conductive resin is in the vicinity of a solidus temperature of solder.

FIG. 9 is a cross-sectional view taken along line A-A′ shown in FIG. 8.

FIG. 10 is a cross-sectional view taken along line B-B′ shown in FIG. 8.

FIG. 11 is a cross-sectional view of the substrate connecting structure using the anisotropic conductive resin shown in FIG. 1 in a state in which the temperature of the thermosetting resin in the anisotropic conductive resin is in the vicinity of a curing reaction peak point.

FIG. 12 is a cross-sectional view taken along line A-A′ shown in FIG. 11.

FIG. 13 is a cross-sectional view taken along line B-B′ shown in FIG. 11.

FIG. 14 is a cross-sectional view of the substrate connecting structure using the anisotropic conductive resin shown in FIG. 1 in a state in which the temperature of the thermosetting resin in the anisotropic conductive resin is in the vicinity of a liquidus temperature of solder.

FIG. 15 is a cross-sectional view taken along line A-A′ shown in FIG. 14.

FIG. 16 is a cross-sectional view taken along line B-B′ shown in FIG. 14.

FIG. 17 is a cross-sectional view of a substrate connecting structure including two electronic components provided on another surface of a second substrate such that the electronic components are placed at positions opposing the anisotropic conductive resin.

FIG. 18 is a cross-sectional view showing a substrate connecting structure using a related-art anisotropic conductive resin.

FIG. 19 is a cross-sectional view taken along line A-A′ shown in FIG. 18.

FIG. 20 is a cross-sectional view taken along line B-B′ shown in FIG. 18.

FIG. 21 is a cross-sectional view of a substrate connecting structure including two electronic components provided in the second substrate such that the electronic components are placed at positions opposing the anisotropic conductive resin.

### MODE FOR IMPLEMENTING THE INVENTION

A preferred embodiment for implementing the present invention is hereunder described in detail by reference to the drawings.

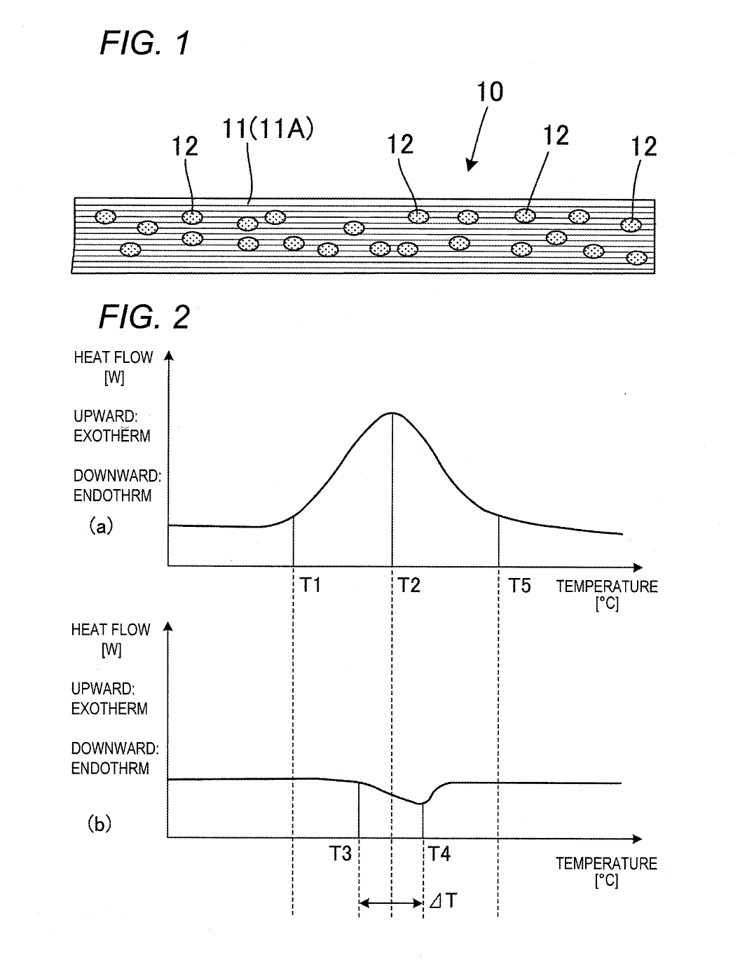

FIG. 1 is a cross-sectional view showing an anisotropic conductive resin of an embodiment of the present invention. In the drawing, an anisotropic conductive resin 10 of the embodiment contains a thermosetting resin 11 and particle solder (an alloy for connecting metals) 12. The solder 12 is, for example, Sn/40Bi/0.1Cu (Sn in an amount of 59.9%, Bi in an amount of 40%, and Cu (copper) in an amount of 0.1%), and a solidus temperature T3 is 139° C., and a liquidus temperature T4 is 170° C. In the case of Sn/40Bi/0.1Cu solder, providing a temperature difference ΔT between the solidus temperature T3 and the liquidus temperature T4, the temperature difference ΔT=31° C., which greater than the temperature difference ΔT=2° C. of related-art Sn/58Bi.

A temperature relationship between the thermosetting resin 11 and the solder 12 is T1<T3<T2<T4, where a reaction start temperature of the thermosetting resin 11 is T1, a reaction peak temperature is T2, a solidus temperature of the solder 12 is T3, and a liquidus temperature of the solder 12 is T4.

FIG. 2 is a diagram showing heat characteristics of the thermosetting resin 11 and the solder 12. FIG. 2(a) located above in the drawing shows a heat characteristic of the thermosetting resin 11, and FIG. 2(b) located below in the drawing shows a heat characteristic of the solder 12. A horizontal axis designates a temperature (° C.), and a vertical axis designates a heat flow (W). The thermosetting resin 11 enters an exothermic state from the reaction start temperature T1 to a reaction end temperature T5. The solder 12 enters an endothermic state from the solidus temperature T3 to the liquidus temperature T4.

A temperature sequence existing between the thermosetting resin 11 and the solder 12 satisfies a relationship of T1<T3<T2<T4, as mentioned previously. In particular, when the reaction end temperature T5 of the thermosetting resin 11 is higher than the liquidus temperature T4 of the solder 12 (i.e., T4<T5), the thermosetting resin 11 is in a soft state even when the solder 12 remains fused. Therefore, when, for example, two substrates are electrically connected by thermocompression bonding, an inter-terminal distance (a gap) between the two substrates is reduced, whereupon a wet spread of the solder 12 to the terminals is accelerated. Specifically, it becomes possible to effectively feed solder between the terminals of the two substrates. In the meantime, in a case where the reaction end temperature T5 of the thermosetting resin 11 is lower than the liquidus temperature T4 of the solder 12 (i.e., T5<T4), even when the solder (solder particles) 12 that does not contribute to connection between the terminals of the two substrates is fused, the thermosetting resin 11 thermally-cured in the vicinity of the solder remains a rigid structure. Therefore, the fused solder (solder particles) 12 in the vicinity of the thermosetting resin hardly contacts one another or fuses together.

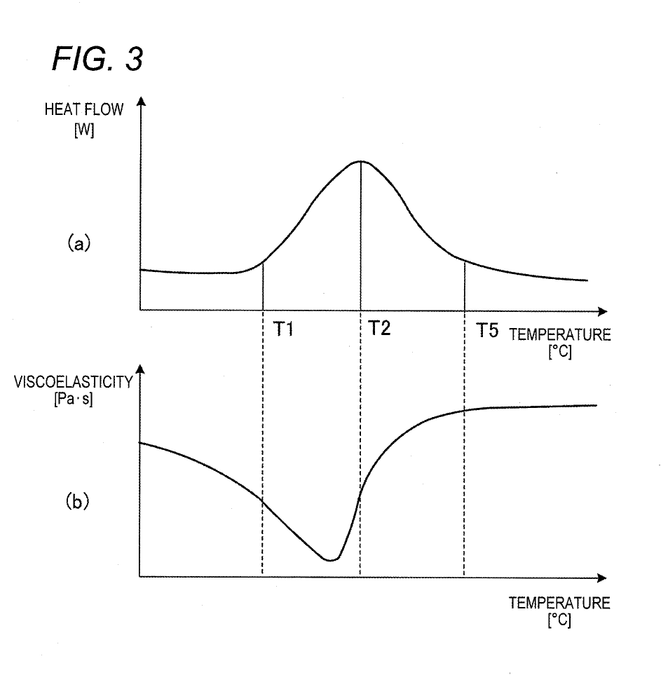

FIG. 3 is a diagram showing the heat characteristic and a viscosity characteristic of the thermosetting resin 11. FIG. 3(a) located above in the drawing shows the heat characteristic of the thermosetting resin 11, and FIG. 3(b) located below in the drawing shows the viscosity characteristic of the same. A horizontal axis relating to the viscosity characteristic designates a temperature (° C.), and a vertical axis relating the viscosity characteristic designates viscoelasticity (Pa·s). Viscosity of the thermosetting resin 11 comes to the minimum melt viscosity before the reaction peak temperature T2. The solidus temperature T3 of the solder 12 is in the vicinity of the temperature for the minimum melt viscosity. The liquidus temperature T4 of the solder 12 is in the vicinity of a temperature at which viscoelasticity is sufficiently increased. The minimum melt viscosity of the thermosetting resin 11 ranges from 100 to 1000 (Pa·S). A range of viscosity is from 2000 to 20000 (Pa·S).

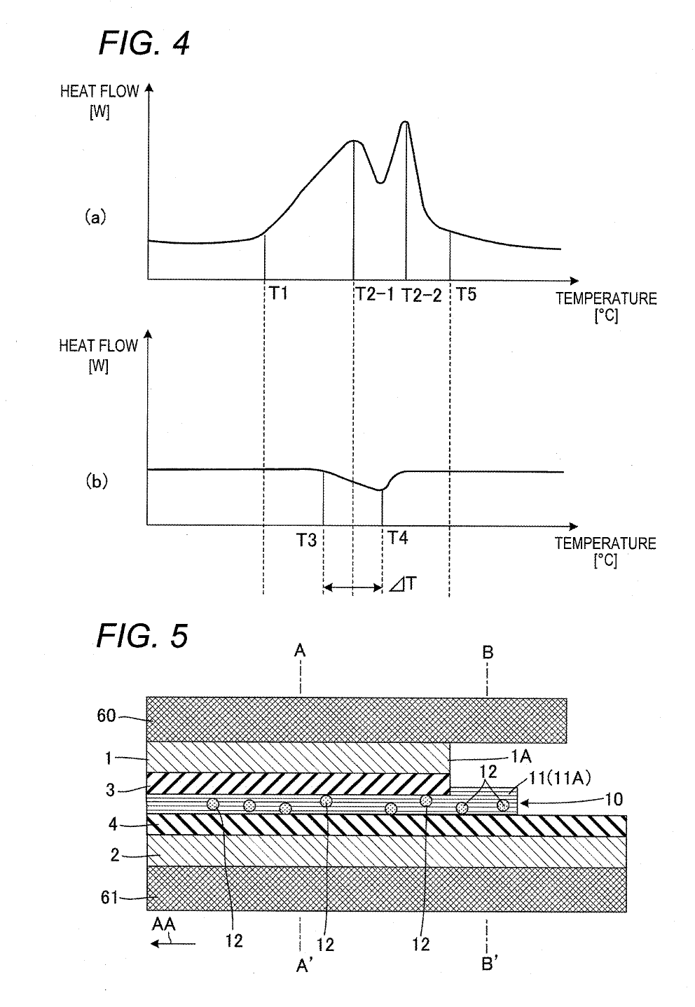

FIG. 4 is a diagram showing a heat characteristic of a thermosetting resin (hereinbelow assigned reference numeral 11A) exhibiting two exothermic reaction peaks and a heat characteristic of the solder 12. FIG. 4(a) located above in the drawing shows a heat characteristic of the thermosetting resin 11A, and FIG. 4(b) located below in the drawing shows a heat characteristic of the solder 12. A horizontal axis designates a temperature (° C.), and a vertical axis designates a heat flow (W). A temperature sequence between the thermosetting resin 11A and the solder 12 satisfies a relationship of T1<T3<T2-1<T4 by adoption of the reaction peak temperature T2-1 of the second peak. Although a temperature sequence of the reaction peak temperature T-2 at the first peak can be disregarded, it is preferable to satisfy a relationship of T1<T3<T2-2<T4 when a sufficiently large temperature difference ΔT (30° C. or more) is acquired.

As described above, the anisotropic conductive resin 10 is a resin in which the solidus temperature T3 of the solder 12 is set between the reaction start temperature T1 and the reaction peak temperature T2 (T2-1) of the thermosetting resin 11 (11A) and in which the liquidus temperature T4 of the solder 12 is set at the reaction peak temperature T2 (T2-1) or more. In a case where two substrates are electrically connected together by thermocompression bonding and by use of the anisotropic conductive resin 10, when the reaction end temperature of the thermosetting resin 11 (11A) is made higher than the liquidus temperature T4 of the solder 12, the thermosetting resin 11 (11A) is not yet completely cured when the solder 12 is fused. Therefore, the inter-terminal distance (gap) between the two substrates is reduced, the wet spread of the solder 12 to the terminals is promoted, and the terminals of the two substrates are reliably connected together. The reaction end temperature of the thermosetting resin 11 (11A) is made lower than the liquidus temperature T4 of the solder 12. Therefore, in relation to the solder 12 not contributing to connection of the terminals of the two substrates (i.e., solder particles existing between the terminals of the two substrates or an outside of the terminals), even when the solder 12 is fused, the thermosetting resin thermally cured in the vicinity of the solder is a rigid structure, the solder particles hardly contact one another or fuse together.

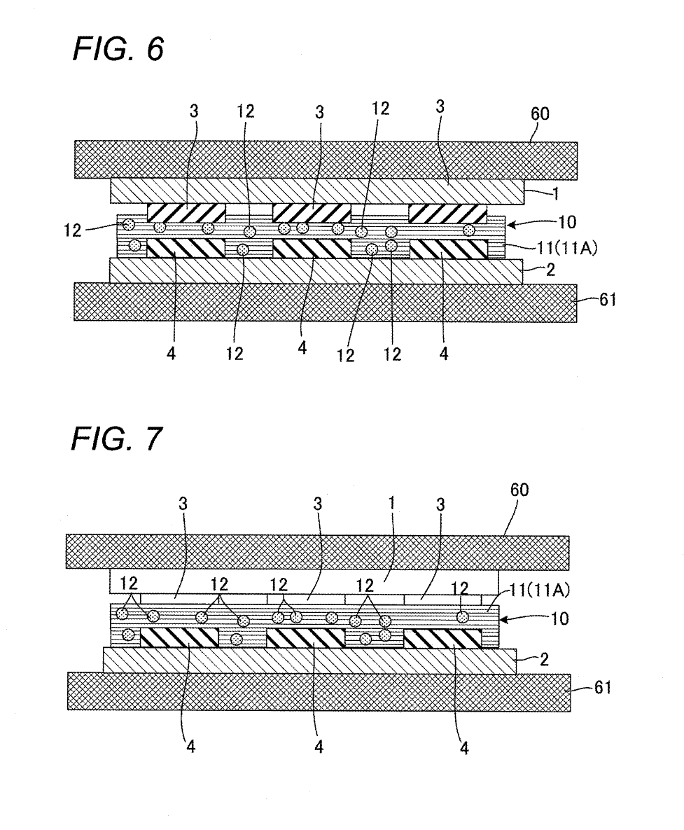

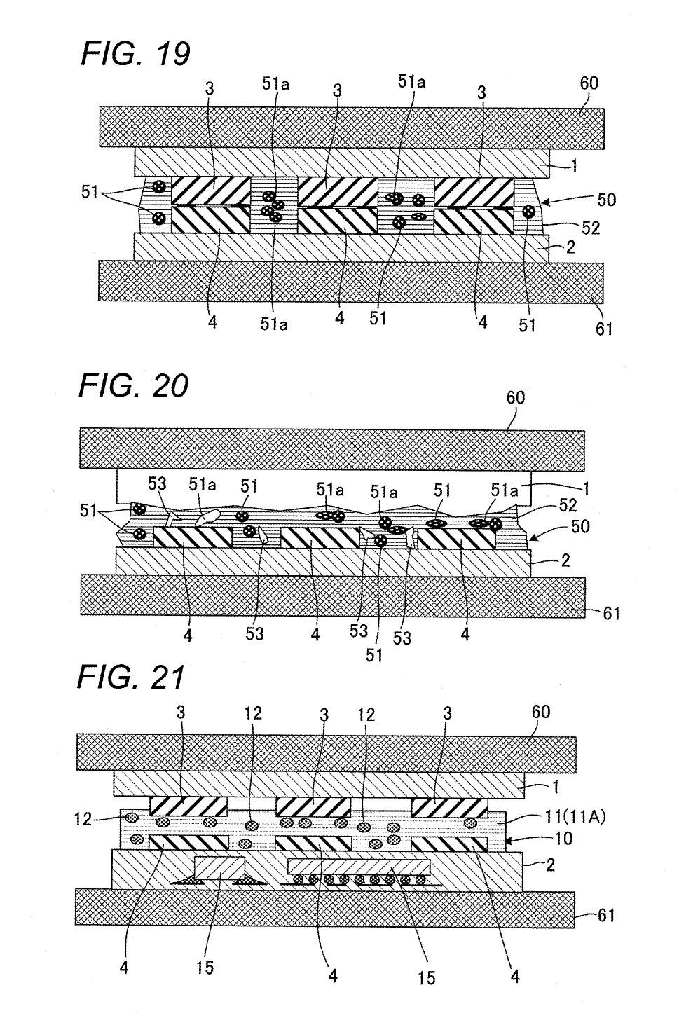

A substrate connecting structure using the anisotropic conductive resin 10 is now described. FIG. 5 is a cross-sectional view showing a substrate connecting structure using the anisotropic conductive resin 10. FIG. 5 is a cross-sectional view of terminals of two substrates cut along their longitudinal direction (a direction designated by arrow AA in FIG. 5 (a predetermined direction)). FIG. 6 is a cross-sectional view taken along line A-A′ shown in FIG. 5, and FIG. 7 is a cross-sectional view taken along line B-B′ shown in FIG. 5. Elements common to FIGS. 18 to 20 are assigned the same reference numerals.

In each of the substrate connecting structures shown in FIGS. 5 to 7, the first substrate 1 having an end face and the second substrate 2 are connected together by the anisotropic conductive resin 10. The first substrate 1 is a flexible substrate made of a translucent soft base member (e.g., polyimide) exhibiting high flexibility, and a plurality of terminals (first and second wiring patterns) 3 are provided on one surface (a first surface) of the first substrate. The second substrate 2 is a rigid substrate made of an opaque hard base member (e.g., an epoxy resin) exhibiting low flexibility. A plurality of terminals (first and second wiring patterns) 4 are provided on one surface (a first surface) of the second substrate. Each of the first substrate 1 and the second substrate 2 is made of a plate-shaped form having the first surface and the second surface opposite to the first surface. The soft base member of the first substrate 1 has an end face 1A intersecting a direction of arrow AA (a predetermined direction). On an of the end face 1A in which the first substrate 1 exists, the terminal 3 of the first substrate 1 oppose the terminal 4 of the second substrate 2. A portion of the anisotropic conductive resin 10 is exposed on an outside opposite to the inside of the end face 1A of the first substrate 1 in which the first substrate 1 exists.

FIGS. 5 through 7 show a state in which the first substrate 1 and the second substrate 2 are subject to heating and pressure bonding while the anisotropic conductive resin 10 is sandwiched between the first surface of the first substrate 1 and the first surface of the second substrate 2, in particular, a state where the temperature of the thermosetting resin 11 (11A) of the anisotropic conductive resin 10 is in the vicinity of the reaction start point. By application of pressure and heat to the first substrate 1 from above, the thermosetting resin 11 of the anisotropic conductive resin 10 becomes softened and spreads. Since the temperature of the solder 12 has not reached the solidus temperature T3 at this time, the solder is in a solid state.

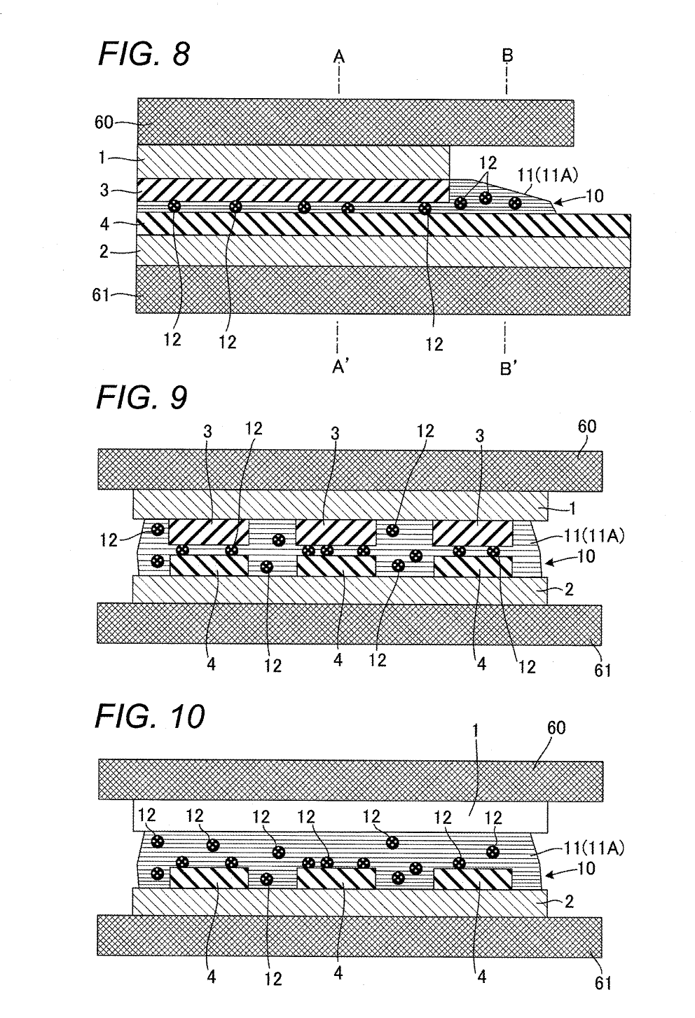

FIGS. 8 through 10 are cross-sectional views showing a state achieved when the temperature of the thermosetting resin 11 of the anisotropic conductive resin 10 is in the vicinity of the solidus temperature T3 of the solder 12. FIG. 8 is a cross-sectional view showing the substrate connecting structure, FIG. 9 is a cross-sectional view taken along line A-A′ shown in FIG. 8, and FIG. 10 is a cross-sectional view taken along line B-B′ shown in FIG. 8.

When the temperature of the thermosetting resin 11 (11A) of the anisotropic conductive resin 10 is in the vicinity of the solidus temperature T3 of the solder 12, the thermosetting resin 11 (11A) further becomes softened and spreads. As a result, particulate solder 12 begins to contact the terminal 3 of the first substrate 1 and the terminal 4 of the second substrate 2. The contacted solder 12 is subject to the breakage of an oxide film, to thus become collapsed.

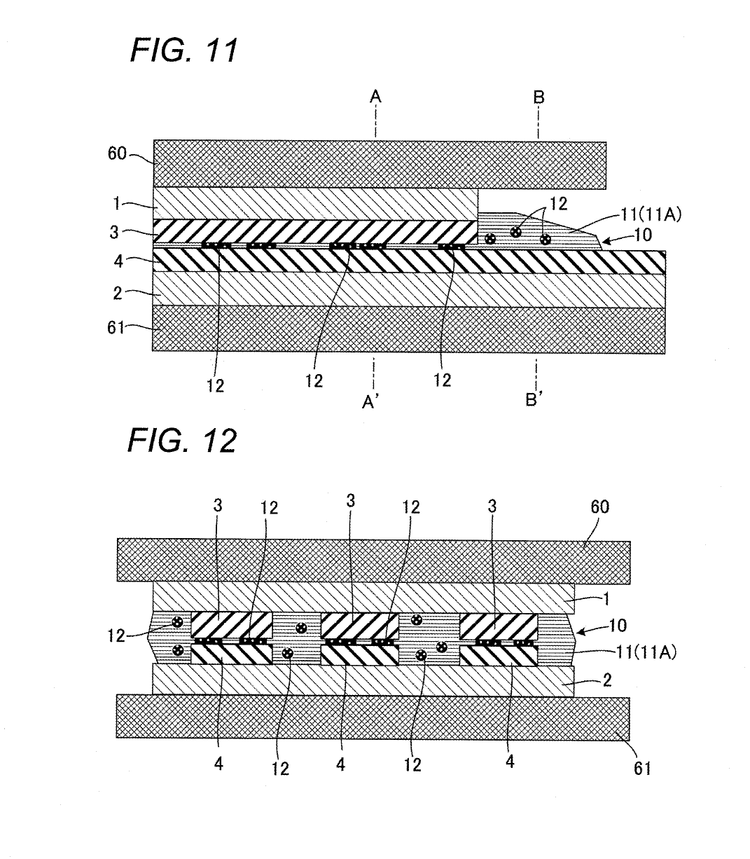

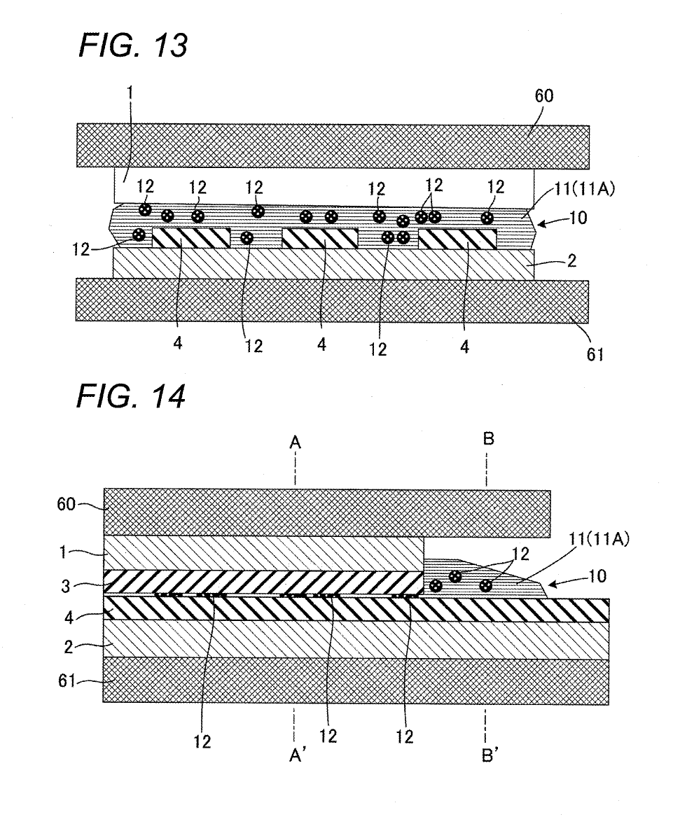

FIGS. 11 to 13 are cross-sectional views showing a state in which the temperature of the thermosetting resin 11 (11A) of the anisotropic conductive resin 10 is in the vicinity of the reaction peak point. In this case, FIG. 11 is a cross-sectional view showing a substrate connecting structure, FIG. 12 is a cross-sectional view taken along line A-A′ shown in FIG. 11, and FIG. 13 is a cross-sectional view taken along line B-B′ shown in FIG. 11.

When the temperature of the thermosetting resin 11 (11A) of the anisotropic conductive resin 10 is in the vicinity of the reaction peak point, the particulate solder 12 becomes collapsed, and the inter-terminal gap between the terminal 3 of the first substrate 1 and the terminal 4 of the second substrate 2 become further smaller, whereby the terminals are connected together by means of the collapsed solder 12. This state arises in all pair of terminals, and all pair of the terminals becomes connected. The thermosetting resin 11 (11A) has already reached a peak of reaction at this time, and a three-dimensional mesh structure is formed, so that the solder particles do not contact one another.

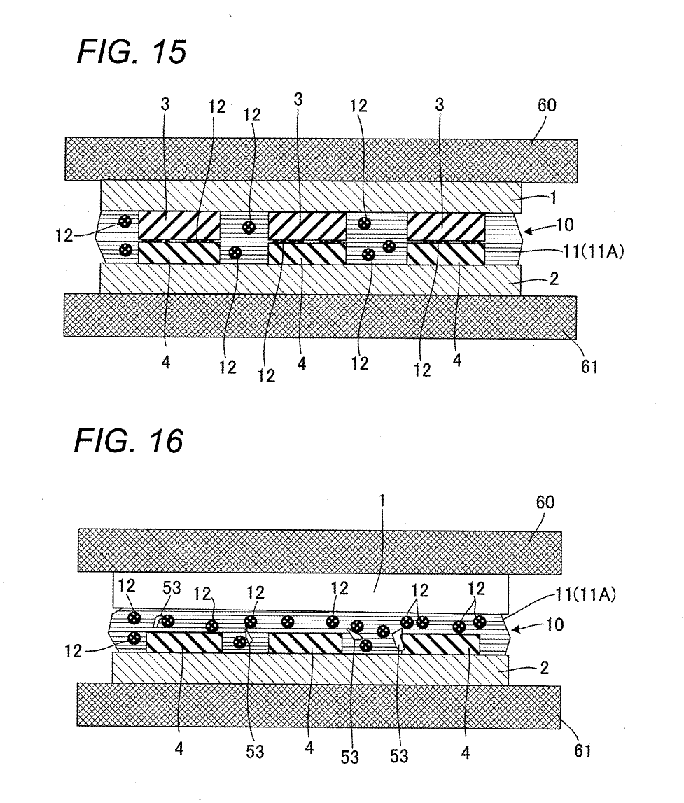

FIGS. 14 through 16 are cross-sectional views showing that the temperature of the thermosetting resin 11 (11A) of the anisotropic conductive resin 10 is in the vicinity of the liquidus temperature T4 of the solder 12. In this case, FIG. 14 is a cross-sectional view showing a substrate connecting structure, FIG. 15 is a cross-sectional view taken along line A-A′ shown in FIG. 14, and FIG. 16 is a cross-sectional view taken along line B-B′ shown in FIG. 14.

When the solder 12 is fused, an alloy layer is formed on a surface of the terminal. When pressure bonding is continually carried out at this time, the thermosetting resin 11 (11A) of the anisotropic conductive resin 10 remains softened, and hence the inter-terminal connection gap between the terminal 3 of the first substrate 1 and the terminal 4 of the second substrate become much smaller. In relation to the particulate solder 12 which exists between the terminals of the first substrate 1, between the terminals of the second substrate, and on the outside of the terminals, even when the solder becomes fused, a cured resin is sturdily present as an insulation film around the solder, whereby the solder particles do not fuse together. Moreover, as shown in FIG. 16, even when the voids 53 are present in the portion of the thermosetting resin 11 (11A) exposed on the outside of the end face 1A of the first substrate 1, the solder particles do not become fused. Therefore, even when moisture is absorbed, neither an electric short circuit nor current leakage occurs.

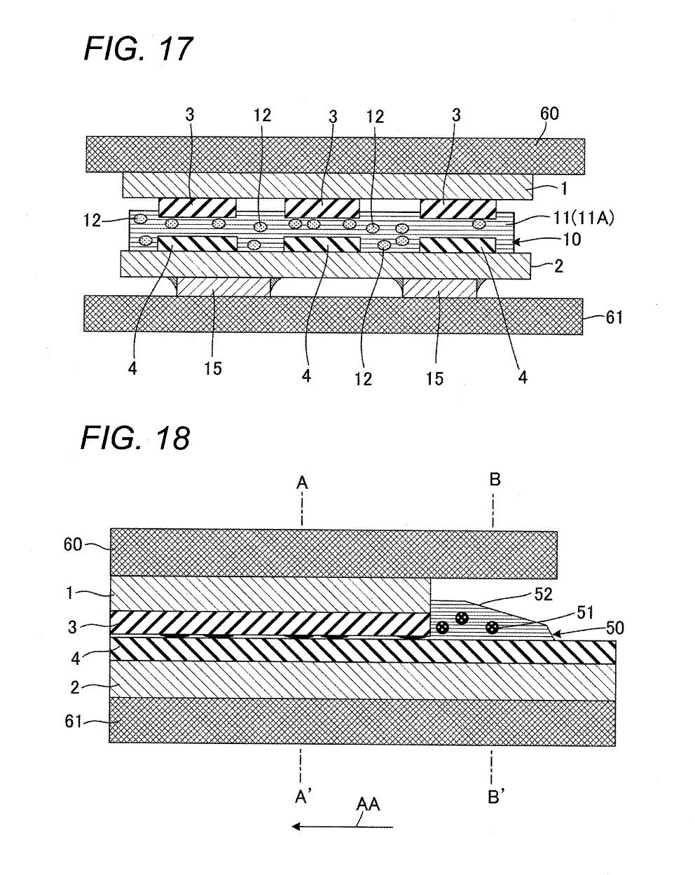

FIG. 17 is a cross-sectional view showing a substrate connecting structure including two electronic components 15 provided on the other surface (second surface) of the second substrate 2 such that the electronic components 15 are disposed at a position opposing the anisotropic conductive resin 10. In the present invention, since thermocompression bonding can be carried out at low pressure, thermocompression bonding can be performed without breakage of the electronic components 15 even when the electronic components 15 are disposed at the position opposing the anisotropic conductive resin 10. Although FIG. 17 shows the two electronic components 15, the number of electronic components is not limited to two, and one electronic component or three or more electronic components may be provided. The electronic components may be general surface-mount components, such as semiconductors (bare chips and packages), mechanical components (connectors, and the like), and functional module components, as well as passive chip components.

FIG. 21 is a cross-sectional view showing a substrate connecting structure including the two electronic components 15 provided in the second substrate 2 such that the electronic components 15 are disposed at a position opposing the anisotropic conductive resin 10. A base member exists between the electronic components 15 and one surface (a first surface) of the second substrate 2, and a base member also exists between the electronic components 15 and the other surface (a second surface) of the second substrate 2. The electronic components 15 are disposed at the position opposing the anisotropic conductive resin 10. In the present invention, thermocompression bonding can be carried out at low pressure. Accordingly, even when the electronic components 15 are disposed at the position opposing the anisotropic conductive resin 10, thermocompression bonding can be carried out without breakage of the electronic components 15. Although FIG. 17 shows the two electronic components 15, the number of electronic components is not limited to two, and one electronic component or three or more electronic components are acceptable. The electronic components may be general electronic components having built-in substrates, such as semiconductors (bare chips and packages), as well as passive chip components.

As described above, the substrate connecting structure includes the anisotropic conductive resin 10, wherein the solidus temperature T3 of the solder 12 is set between the reaction start temperature T1 and the reaction peak temperature T2 (T2-1) of the thermosetting resin 11 (11A) and wherein the liquidus temperature T4 of the solder 12 is set at the reaction peak temperature T2 (T2-1) or more. The reaction end temperature of the thermosetting resin 11 (11A) is made higher than the liquidus temperature T4 of the solder during thermocompression bonding, whereby the thermosetting resin 11 (11A) is not yet fully cured when the solder 12 remains fused. Therefore, the inter-terminal distance between the first substrate 1 and the second substrate 2 becomes smaller, and the wet spread of the solder 12 to the terminals is promoted, whereby the terminals on the two substrates are reliably connected together. Further, in a case where the reaction end temperature of the thermosetting resin 11 (11A) is made lower than the liquidus temperature T4 of the solder, even when solder particles that do not contribute to connection between the terminal of the first substrate 1 and the terminal of the second substrate 2 (solder particles existing between terminals of each of the two substrates 1 and 2 or on the outside of the terminals) are fused, the thermosetting resin thermally cured in the vicinity of the solder remains a rigid structure. Therefore, the solder particles hardly contact one another or fuse together.

In the embodiment, the first substrate 1 and the second substrate 2 are taken as mere substrates having the terminals 3 and 4. However, the substrate may also be a portion of a module configured by electronic components. Moreover, electronic components may be mounted on a rear surface of a substrate to be connected. This is because since terminals are connected together by solder particles that become fused at a connection temperature, connection can be established at smaller load when compared with connection established by metal particles or resin particles plated with metal that remain unfused at the connection temperature, and an electronic component which may be broken at heavy load is not broken. A conceivable substrate is generally a rigid substrate made of an epoxy resin or a flexible substrate made of polyimide. However, the substrate is not limited these substrates. The substrate may be a substrate including surface-mounted IC components, or the like, sealed with a resin, a substrate including IC components, or the like, embedded between substrate layers, and a substrate including electronic components arranged on a mount surface of the substrate and a resin provided on the mount surface so as to cover the electronic components.

The present invention can be applied an electronic device, such as a portable phone, which can provide the electronic device with high reliability in which terminals of two substrates provided in the electronic device can reliably be connected together, and in which occurrence of current leakage or an electric short circuit between terminals caused when a resin absorbs moisture is prevented. Further, a connection can be established at low load, and hence the present invention can also be applied to assembly of a fragile module having poor heat resistance which cannot be subjected to normal soldering, such as connection of flexible substrates of a liquid-crystal module and connection of flexible substrates of constituent components of a camera module.

Although the present invention has been described in detail by reference to a specific embodiment, it is apparent to those skilled in the art to which the present invention pertains that various changes or modifications may be made without departing from the spirit and scope of the present invention.

The present patent application is based on Japanese Patent Application (Application No. 2008-324611) filed on Dec. 19, 2008, the entire contents of which are incorporated herein by reference.

### INDUSTRIAL APPLICABILITY

The present invention provides an advantage in which when the first and second substrates are electrically connected through thermocompression bonding by use of the anisotropic conductive resin including the thermosetting resin and the solder, the terminal of the first substrate is reliably connected to the terminal of the second substrate by setting the reaction end temperature of the thermosetting resin higher than the liquidus temperature of the solder, and also provides an advantage in which solder particles hardly contact with one another or fuse together between the terminals of each of the first and second substrates or the outside of the terminals by setting the reaction end temperature of the thermosetting resin lower than the liquidus temperature of the solder. The present invention can apply to an electronic device, such as a portable phone.

### DESCRIPTIONS OF THE REFERENCE NUMERALS AND SYMBOLS

1 First Substrate

1A End Face of First Substrate

2 Second Substrate

3, 4 Terminal

10 Anisotropic Conductive Resin

11, 11A Thermosetting Resin

12 Solder

15 Electronic Component

53 Void

60 Thermocompression Bonding Tool

61 Compression Bonding Table

1. An anisotropic conductive resin comprising:
a thermosetting resin and an alloy,
wherein a relationship of T1<T3<T2<T4<T5 is satisfied,
where
T1 is a reaction start temperature of the thermosetting resin,
T2 is a reaction peak temperature of the thermosetting resin,
T3 is a solidus temperature of the alloy,
T4 is a liquidus temperature of the alloy,
T5 is a reaction end temperature of the thermosetting resin.

2. A substrate connecting structure comprising:
first and second substrates, each of which comprises:
a base member having a first surface and a second surface opposite to the first surface; and
first and second wiring patterns arranged on the first surface and extending along a predetermined direction; and
an anisotropic conductive resin interposed between the first surface of the first substrate and the first surface of the second substrate,
wherein the base member of the first substrate has an end face intersecting the predetermined direction,
wherein on an inside of the end face in which the first substrate exists, the first wiring pattern of the first substrate opposes the first wiring pattern of the second substrate, and the second wiring pattern of the first substrate opposes the second wiring pattern of the second substrate, and
wherein on an outside of the end face which is opposite to the inside, the anisotropic conductive resin is exposed.

3. The substrate connecting structure according to claim 2,
wherein the first substrate or the second substrate is a part of an electronic component.

4. The substrate connecting structure according to claim 2, comprising:
a first electronic component provided on the second surface of the second substrate,
wherein the first electronic component is disposed at a position opposing the anisotropic conductive resin across the second substrate.

5. The substrate connecting structure according to claim 2, comprising:
a second electronic component provided in the base member of the second substrate,
wherein the second electronic component is disposed at a position opposing the anisotropic conductive resin across the base member of the second substrate.

6. An electronic device comprising:
the anisotropic conductive resin according to claim 1; or
the substrate connecting structure according to claim 2.
